(19) United States
(12) Patent Application Publication
(10) Pub. No.: US 2025/0229532 A1
(43) Pub. Date: Jul. 17, 2025

(54) FLEXIBLE BOARD, LIQUID JET HEAD, AND LIQUID JET RECORDING APPARATUS

(71) Applicant: SII Printek Inc., Chiba-shi (JP)

(72) Inventor: Yukihiro SAGA, Chiba-shi (JP)

(21) Appl. No.: 19/017,121

(22) Filed: Jan. 10, 2025

(30) Foreign Application Priority Data
Jan. 17, 2024 (JP) 2024-005524

(51) Int. Cl. B41J 2/14; H05K 1/02

(52) U.S. Cl. CPC B41J 2/14201; B41J 2002/14491; H05K 1/0277; H05K 2201/2009

(57) ABSTRACT

A flexible board and so on capable of improving the reliability are provided. The flexible board according to an embodiment of the present disclosure is a flexible board configured to output a drive signal to be applied to a liquid jet head having a plurality of nozzles, including at least one drive device which is disposed on a board surface, and which is configured to generate the drive signal configured to jet a liquid from the nozzles, a terminal section as a portion which is disposed in an end-portion region of the board surface, and which is inserted into a connector on another board, a reinforcing plate which is disposed including the terminal section at a first end portion side on the board surface, and which is configured to adjust a thickness of the board surface, and a stress relaxation part which is disposed in a vicinity of a second end portion at an opposite side to the first end portion in the reinforcing plate, and which is configured to relax stress generated when the flexible board bends.

### RELATED APPLICATIONS

This application claims priority to Japanese Patent application No. JP2024-005524, filed on Jan. 17, 2024, the entire content of which is incorporated herein by reference.

### BACKGROUND OF THE INVENTION

### 1. Field of the Invention

The present disclosure relates to a flexible board, a liquid jet head, and a liquid jet recording apparatus.

### 2. Description of the Related Art

Liquid jet recording apparatuses equipped with liquid jet heads are used in a variety of fields, and a variety of types of liquid jet heads are developed.

In such liquid jet heads, in general, it is required to easily improve the reliability.

Therefore, it is desirable to provide a flexible board, a liquid jet head, and a liquid jet recording apparatus capable of easily improving the reliability.

### SUMMARY OF THE INVENTION

The flexible board according to an embodiment of the present disclosure is a flexible board configured to output a drive signal to be applied to a liquid jet head having a plurality of nozzles, including at least one drive device which is disposed on a board surface, and which is configured to generate the drive signal configured to jet a liquid from the nozzles, a terminal section as a portion which is disposed in an end-portion region of the board surface, and which is inserted into a connector on another board, a reinforcing plate which is disposed including the terminal section at a first end portion side on the board surface, and which is configured to adjust a thickness of the board surface, and a stress relaxation part which is disposed in a vicinity of a second end portion at an opposite side to the first end portion in the reinforcing plate, and which is configured to relax stress generated when the flexible board bends.

A liquid jet head according to an embodiment of the present disclosure includes the flexible board according to the embodiment of the present disclosure described above, and a jet section which includes a plurality of nozzles configured to jet the liquid based on the drive signal output from the flexible board.

A liquid jet recording apparatus according to an embodiment of the present disclosure includes the liquid jet head according to the embodiment of the present disclosure.

According to the flexible board, the liquid jet head, and the liquid jet recording apparatus related to an embodiment of the present disclosure, it becomes possible to improve the reliability.

### BRIEF DESCRIPTION OF THE DRAWINGS

FIG. 1 is a block diagram showing an outline configuration example of a liquid jet recording apparatus according to an embodiment of the present disclosure.

FIG. 2 is a perspective view schematically showing an outline configuration example of a liquid jet head shown in FIG. 1.

FIG. 3 is a cross-sectional view schematically showing a configuration example of the liquid jet head shown in FIG. 2.

FIG. 4 is a plan view schematically showing an outline configuration example of flexible boards shown in FIG. 2 and FIG. 3.

FIG. 5 is a cross-sectional view schematically showing an outline configuration example of the flexible board shown in FIG. 4.

FIG. 6 is a plan view schematically showing a configuration example of a flexible board according to Comparative Example 1.

FIG. 7 is a plan view schematically showing a configuration example of a flexible board according to Practical Example 1.

FIG. 8 is a plan view schematically showing a configuration example of a flexible board according to Practical Example 2.

FIG. 9 is a plan view schematically showing a configuration example of a flexible board according to Comparative Example 2.

FIG. 10 is a plan view schematically showing a configuration example of a flexible board according to Practical Example 3.

FIG. 11 is a plan view schematically showing a configuration example of a flexible board according to Practical Example 4.

FIG. 12 is a plan view schematically showing a configuration example of a flexible board according to Practical Example 5.

### DETAILED DESCRIPTION OF THE PREFERRED EMBODIMENTS

An embodiment of the present disclosure will hereinafter be described in detail with reference to the drawings. It should be noted that the description will be presented in the following order.

1. Embodiment (examples of flexible boards including stress relaxation parts having a variety of configurations)

### 2. Modified Examples

### 1. Embodiment

### [Outline Configuration of Printer 5]

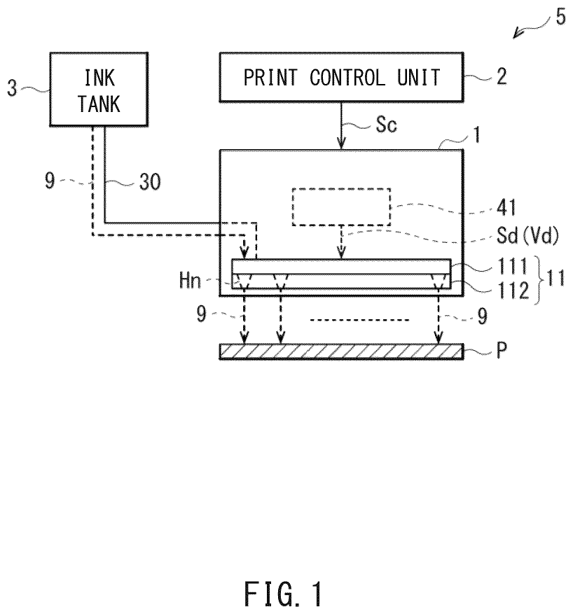

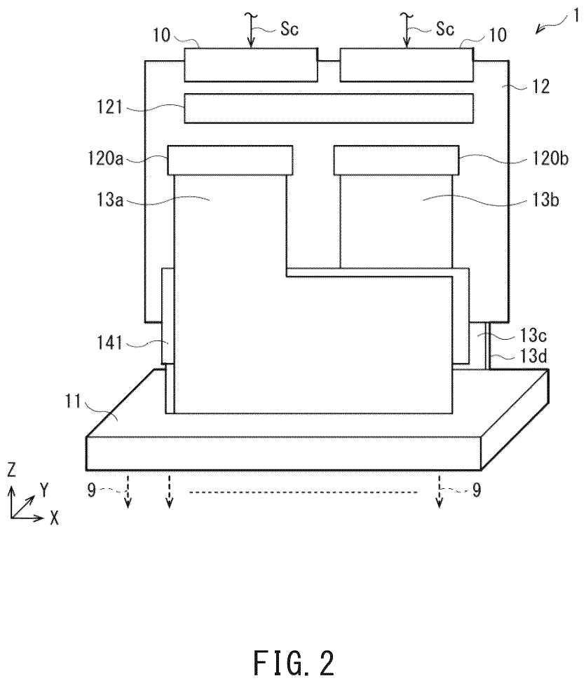

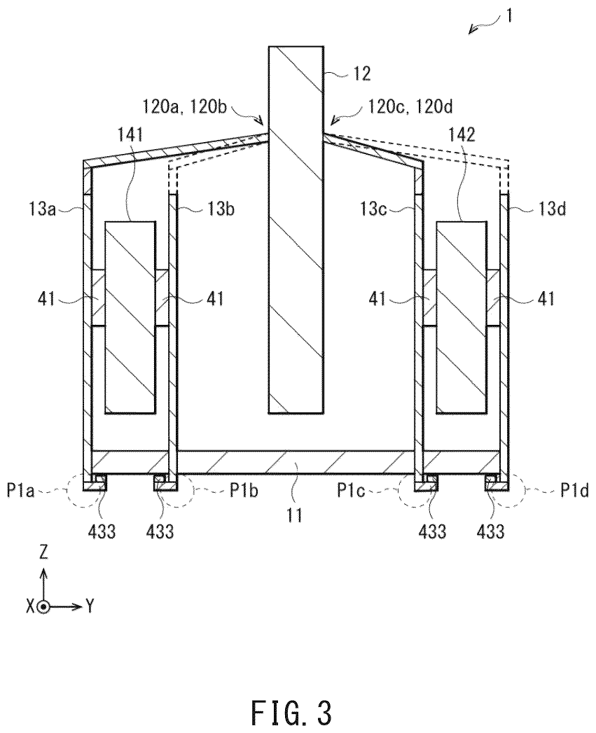

FIG. 1 is a block diagram showing an outline configuration example of a printer 5 as a liquid jet recording apparatus according to an embodiment of the present disclosure. FIG. 2 is a perspective view schematically showing an outline configuration example of an inkjet head 1 as a liquid jet head shown in FIG. 1. FIG. 3 is a cross-sectional view (a Y-Z cross-sectional view) schematically showing a configuration example of the inkjet head 1 shown in FIG. 2. It should be noted that a scale size of each of the members is accordingly altered so that the member is shown in a recognizable size in the drawings used in the description of the present specification.

The printer 5 is an inkjet printer for performing recording (printing) of images, characters, and the like on a recording target medium (e.g., recording paper P shown in FIG. 1) using ink 9 described later. As shown in FIG. 1, the printer 5 is provided with the inkjet head 1, a print control unit 2, and an ink tank 3.

It should be noted that the inkjet head 1 corresponds to a specific example of a “liquid jet head” in the present disclosure, and the printer 5 corresponds to a specific example of a “liquid jet recording apparatus” in the present disclosure. Further, the ink 9 corresponds to a specific example of a “liquid” in the present disclosure.

### (A. Print Control Unit 2)

The print control unit 2 is for supplying the inkjet head 1 with a variety of types of information (data). Specifically, as shown in FIG. 1, the print control unit 2 is arranged to supply each of constituents (drive devices 41 described later and so on) in the inkjet head 1 with a print control signal Sc. It should be noted that the print control signal Sc is arranged to include, for example, image data, an ejection timing signal, and a power-supply voltage for making the inkjet head 1 operate.

### (B. Ink Tank 3)

The ink tanks 3 are tanks for containing the ink 9 inside. As shown in FIG. 1, it is arranged that the ink 9 in the ink tank 3 is supplied to the inside (a jet section 11 described later) of the inkjet head 1 via an ink supply tube 30. It should be noted that such an ink supply tube 30 is formed of, for example, a flexible hose having flexibility.

### (C. Inkjet Head 1)

The inkjet head 1 is a head for jetting (ejecting) the ink 9 shaped like a droplet from a plurality of nozzle holes Hn described later to the recording paper P as represented by dotted arrows in FIG. 1 to thereby perform recording of images, characters, and so on. As shown in, for example, FIG. 2 and FIG. 3, the inkjet head 1 is provided with a single jet section 11, a single I/F (interface) board 12, four flexible boards 13a, 13b, 13c, and 13d, and two cooling units 141, 142.

### (C-1. I/F Board 12)

As shown in FIG. 2 and FIG. 3, the I/F board 12 is provided with two connectors 10, four connectors 120a, 120b, 120c, and 120d, and a circuit arrangement area 121.

As shown in FIG. 2, the connectors 10 are each a part (a connector part) for inputting the print control signal Sc which is described above, and which is supplied from the print control unit 2 toward the inkjet head 1 (the flexible boards 13a, 13b, 13c, and 13d described later). The connectors 120a, 120b, 120c, and 120d are parts (connector parts) for electrically coupling the I/F board 12 and the flexible boards 13a, 13b, 13c, and 13d, respectively.

The circuit arrangement area 121 is an area where a variety of circuits are arranged on the I/F board 12. It should be noted that it is also possible to arrange that such a circuit arrangement area is also disposed in other regions on the I/F board 12.

### (C-2. Jet Section 11)

As shown in FIG. 1, the jet section 11 is a part which has the plurality of nozzle holes Hn, and which jets the ink 9 from these nozzle holes Hn. It is arranged that such jet of the ink 9 is performed in accordance with drive signals Sd (drive voltages Vd) supplied from the drive devices 41 described later on each of the flexible boards 13a, 13b, 13c, and 13d (see FIG. 1).

As shown in FIG. 1, such a jet section 11 is configured including an actuator plate 111 and a nozzle plate 112.

### (Nozzle Plate 112)

The nozzle plate 112 is a plate formed of a film material such as polyimide, or a metal material, and has the plurality of nozzle holes Hn described above as shown in FIG. 1. These nozzle holes Hn are formed side by side at predetermined intervals, and each have, for example, a circular shape. It should be noted that these nozzle holes Hn each correspond to a specific example of a “nozzle” in the present disclosure.

In the example of the jet section 11 shown in FIG. 2, the jet section 11 is configured with a plurality of nozzle arrays (four nozzle arrays) each of which has the plurality of nozzle holes Hn in the nozzle plate 112 arranged along an array direction (an X-axis direction). Further, these four nozzle arrays are arranged side by side along a direction (a Y-axis direction) perpendicular to the array direction.

### (Actuator Plate 111)

The actuator plate 111 is a plate formed of a piezoelectric material such as PZT (lead zirconate titanate). The actuator plate 111 is provided with a plurality of channels (pressure chambers). These channels are each a part for applying pressure to the ink 9, and are arranged side by side so as to be parallel to each other at predetermined intervals. Each of the channels is partitioned with drive walls (not shown) formed of a piezoelectric body, and forms a groove part having a recessed shape in a cross-sectional view.

As such channels, there exist ejection channels for ejecting the ink 9, and dummy channels (non-ejection channels) which do not eject the ink 9. In other words, it is arranged that the ejection channels are filled with the ink 9 on the one hand, but the dummy channels are not filled with the ink 9 on the other hand. It should be noted that it is arranged that filling of each of the ejection channels with the ink 9 is performed via, for example, a flow channel (a common flow channel) commonly communicated with such ejection channels. Further, it is arranged that each of the ejection channels is individually communicated with the nozzle hole Hn in the nozzle plate 112 on the one hand, but each of the dummy channels is not communicated with the nozzle hole Hn on the other hand. These ejection channels and dummy channels are alternately arranged side by side along the array direction (the X-axis direction) described above.

Further, on the inner side surfaces opposed to each other in the drive walls described above, there are respectively disposed drive electrodes. As the drive electrodes, there exist common electrodes disposed on the inner side surfaces facing the ejection channels, and active electrodes (individual electrodes) disposed on the inner side surfaces facing the dummy channels. These drive electrodes and the drive devices 41 described later are electrically coupled to each other via each of the flexible boards 13a, 13b, 13c, and 13d. Thus, it is arranged that the drive voltages Vd (the drive signals Sd) described above are applied to the drive electrodes from the drive devices 41 via each of the flexible boards 13a, 13b, 13c, and 13d (see FIG. 1).

### (C-3. Flexible Boards 13a, 13b, 13c, and 13d)

The flexible boards 13a, 13b, 13c, and 13d are each a board for electrically coupling the I/F board 12 and the jet section 11 to each other as shown in FIG. 2 and FIG. 3. These flexible boards 13a, 13b, 13c, and 13d are arranged to individually control jet actions of the ink 9 in the four nozzle arrays in the nozzle plate 112 described above, respectively. Further, as indicated by the reference symbols P1a, P1b, P1c, and P1d in, for example, FIG. 3, it is arranged that the flexible boards 13a, 13b, 13c, and 13d are folded around places (around pressure-bonding electrode parts 433) where the flexible boards 13a, 13b, 13c, and 13d are coupled to the jet section 11, respectively. It should be noted that it is arranged that electrical coupling between the pressure-bonding electrode parts 433 and the jet section 11 is achieved by, for example, thermocompression bonding using an anisotropic conductive film (ACF). Further, for example, it may be arranged that other flexible boards having only the wiring lines are further ACF-bonded to the flexible boards 13a, 13b, 13c, and 13d, and those other flexible boards and the jet section 11 are ACF-bonded to each other.

On each of such flexible boards 13a, 13b, 13c, and 13d (on a wiring layer at an obverse surface S1 side described later), there is individually mounted the single drive device or a plurality of drive devices 41 (see FIG. 3). These drive devices 41 are each a device for outputting the drive signals Sd (the drive voltages Vd) for jetting the ink 9 from the nozzle holes Hn in the corresponding nozzle array in the jet section 11. Therefore, it is arranged that such drive signals Sd are output from each of the flexible boards 13a, 13b, 13c, and 13d to the jet section 11. It should be noted that such drive devices 41 are each formed of, for example, an application specific integrated circuit (ASIC).

Further, these drive devices 41 are arranged to be cooled by the cooling units 141, 142 described above. Specifically, as shown in FIG. 3, the cooling unit 141 is fixedly arranged between the drive devices 41 on the flexible boards 13a, 13b, and by pressing the cooling unit 141 against each of these drive devices 41, the drive devices 41 are cooled. Similarly, the cooling unit 142 is fixedly arranged between the drive devices 41 on the flexible boards 13c, 13d, and by pressing the cooling unit 142 against each of these drive devices 41, the drive devices 41 are cooled. It should be noted that such cooling units 141, 142 can each be configured using a variety of types of cooling mechanisms.

[Detailed Configuration of Flexible Boards 13a, 13b, 13c, and 13d]

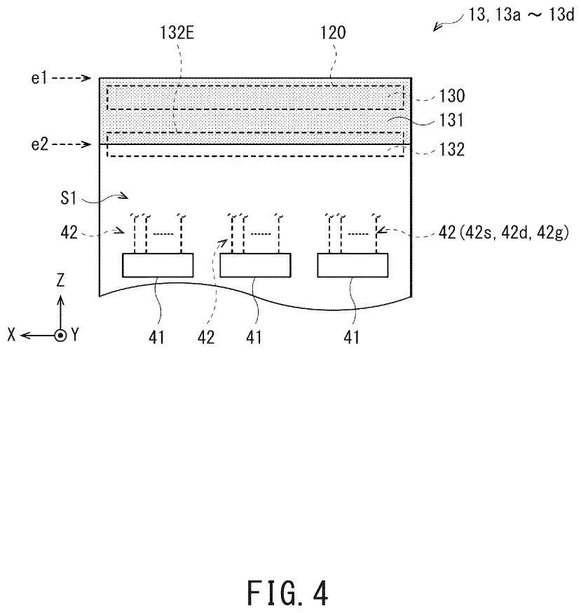

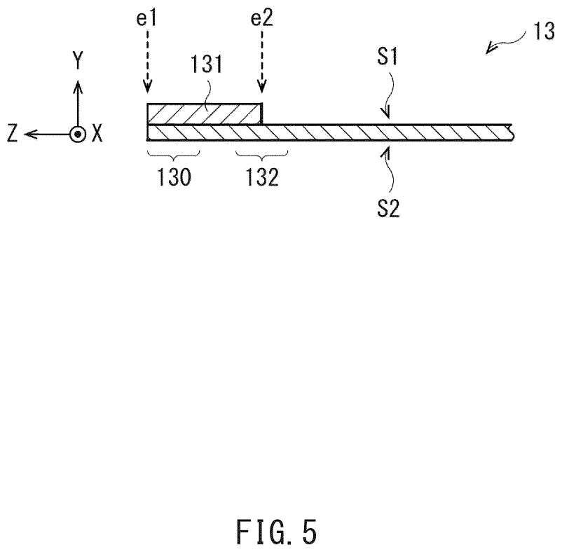

Subsequently, a detailed configuration example of the flexible boards 13a, 13b, 13c, and 13d described above will be described with reference to FIG. 4 and FIG. 5 in addition to FIG. 1 to FIG. 3.

FIG. 4 is a plan view (a Z-X plan view) schematically showing an outline configuration example of the flexible boards 13a to 13d (hereinafter collectively referred to as flexible boards 13 as appropriate) shown in FIG. 2 and FIG. 3. FIG. 5 is a cross-sectional view (a Y-Z cross-sectional view) schematically showing an outline configuration example of the flexible boards 13 shown in FIG. 4.

First, the flexible boards 13 are each formed as a double-sided board with a multilayered structure including the obverse surface S1 and a reverse surface S2. Specifically, the flexible boards 13 each have a first wiring layer at the obverse surface S1 side and a second wiring layer at the reverse surface S2 side opposed to each other along a direction (the Y-axis direction) perpendicular to a board surface (a Z-X plane) as wiring layers of such a multilayer structure (a double-layered structure).

It should be noted that it is possible to adopt a structure in which the wiring layers in the flexible board 13 are, for example, three or more layers including the first wiring layer and the second wiring layer described above.

Further, as shown in FIG. 4 and FIG. 5, the flexible boards 13 each have the single drive device 41 or the plurality of drive devices 41 (three drive devices 41 in this example) described above, wiring patterns 42, a terminal section 130, a reinforcing plate 131, and a stress relaxation part 132.

As described above, the drive devices 41 are disposed on (the first wiring layer at the obverse surface S1 side of) the flexible board 13. Further, in the example shown in FIG. 4, the plurality of drive devices 41 (the three drive devices 41 in this example) are arranged side by side along the X-axis direction on the flexible board 13.

As shown in FIG. 4, the wiring patterns 42 are patterns of a variety of wiring lines to be electrically coupled to the drive devices 41. As the wiring patterns 42, there are included signal wiring patterns 42s corresponding to wiring lines of a variety of signals, power supply wiring patterns 42d corresponding to wiring lines of a variety of power supplies, and ground wiring patterns 42g corresponding to the ground wiring lines.

The terminal section 130 is arranged (see FIG. 4) in an end-portion region at the I/F board 12 side in the obverse surface S1 of the flexible board 13, and includes a plurality of terminals (terminals T described later) for electrically coupling the flexible board 13 and the I/F board 12 to each other. In other words, the terminal section 130 is a portion to be inserted into one of the connectors 120a to 120d on the I/F board 12 as another board.

The reinforcing plate 131 is a member which is disposed so as to include the terminal section 130 at a first end portion e1 side on the flexible board 13 (on the first wiring layer at the obverse surface S1 side) (see FIG. 4 and FIG. 5), and which adjusts the thickness of a board surface of the flexible board 13.

The stress relaxation part 132 is disposed in the vicinity of a second end portion e2 at an opposite side to the first end portion e1 in the reinforcing plate 131 (at the arrangement area side of the drive device 41) (see FIG. 4 and FIG. 5), and is arranged to relax the stress generated when the flexible board 13 bends, as described later in detail.

### [Practical Examples Related to Configuration of Stress Relaxation Part 132]

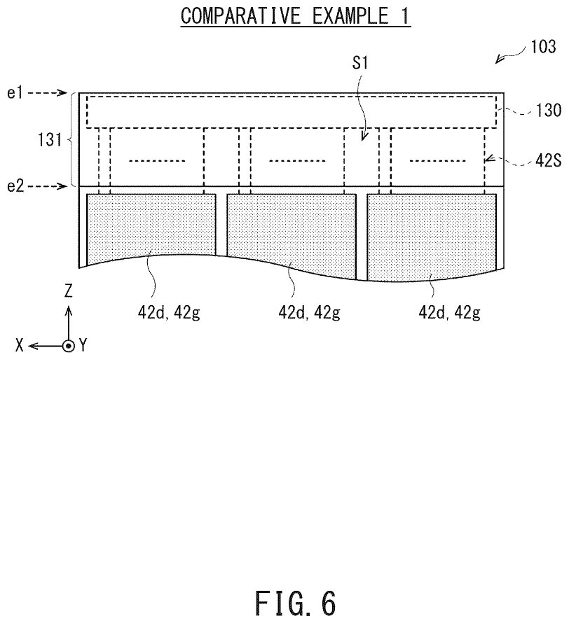

Here, practical examples (Practical Examples 1 to 5) related to the configuration of such a stress relaxation part 132 will be described in detail compared to the configuration of comparative examples (Comparative Examples 1, 2) with reference to FIG. 6 to FIG. 12 in addition to FIG. 1 to FIG. 5.

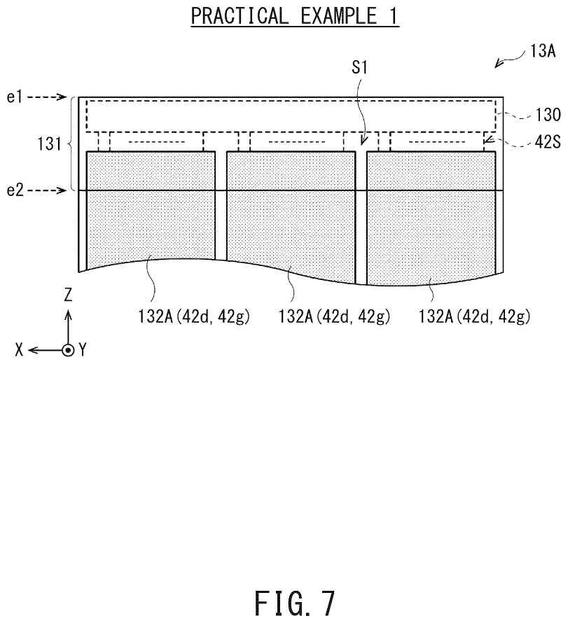

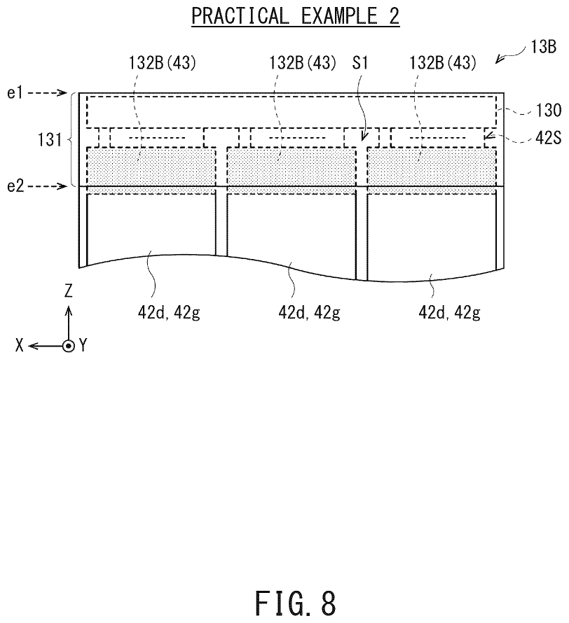

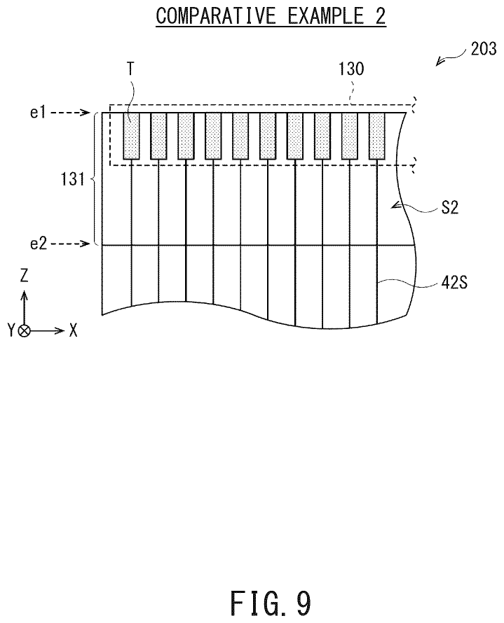

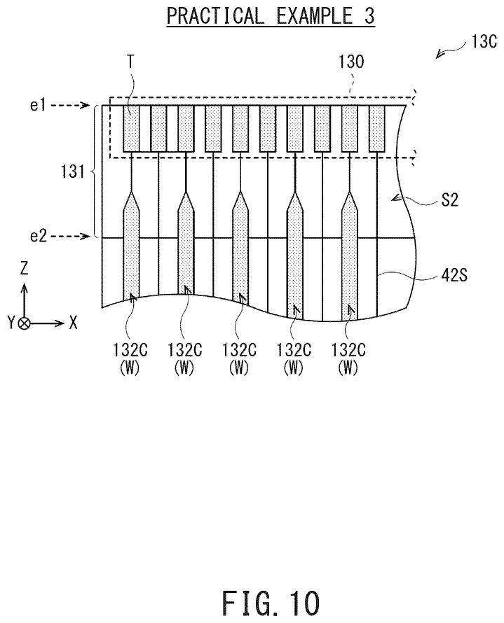

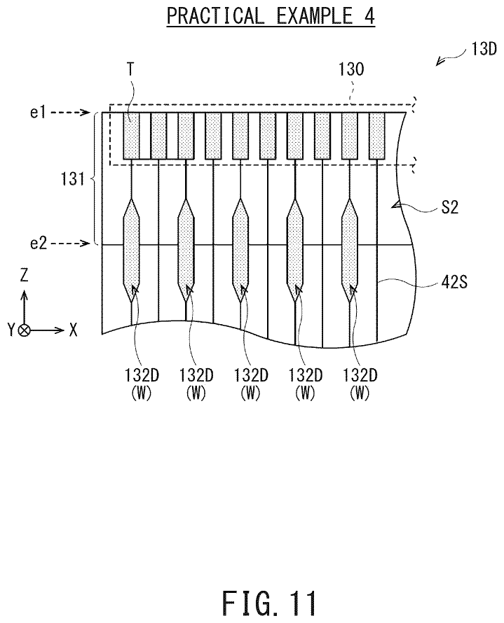

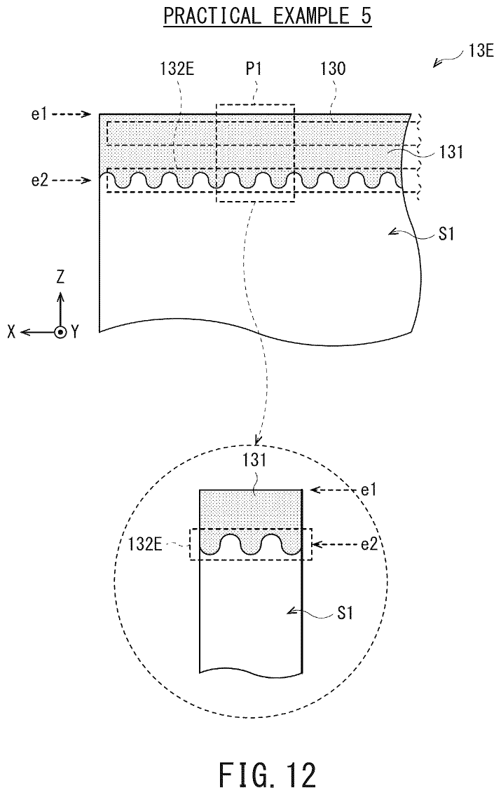

FIG. 6 and FIG. 9 are plan views (Z-X plan views) schematically showing configuration examples of flexible boards (flexible boards 103, 203) according to Comparative Examples 1, 2, respectively. Further, FIG. 7, FIG. 8, FIG. 10, FIG. 11, and FIG. 12 are plan views (Z-X plan views) schematically showing configuration examples of flexible boards (flexible boards 13A to 13E) according to Practical Examples 1 to 5, respectively. It should be noted that in FIG. 12, an enlarged configuration of a place indicated by a symbol P1 is additionally illustrated in a region represented by dotted lines.

### Comparative Example 1

First, in a flexible board 103 in Comparative Example 1 shown in FIG. 6, unlike a flexible board 13A in Practical Example 1 described below, the power supply wiring patterns 42d and the ground wiring patterns 42g are disposed at inner side (the drive device 41 side) of the second end portion e2 of the reinforcing plate 131. In other words, in this flexible board 103, the power supply wiring patterns 42d and the ground wiring patterns 42g are not disposed so as to straddle the second end portion e2 of the reinforcing plate 131 on the board surface. Therefore, as described later in detail, the risk that a crack caused by the bend of the flexible board 103 occurs in the vicinity of the second end portion e2 of the reinforcing plate 131 is made high.

### Practical Examples 1 to 4

In contrast, the flexible boards 13A to 13D in Practical Examples 1 to 4 shown in FIG. 7, FIG. 8, FIG. 10, and FIG. 11 are all configured as follows. That is, in all of these flexible boards 13A to 13D, the reinforcing patterns which function as the stress relaxation parts 132 (132A to 132D) described above are disposed so as to straddle the second end portion e2 of the reinforcing plate 131 on the board surface.

Specifically, in the flexible board 13A in Practical Example 1 shown in FIG. 7, the reinforcing patterns which function as the stress relaxation parts 132A are formed using the power supply wiring patterns 42d or the ground wiring patterns 42g. In other words, the power supply wiring patterns 42d or the ground wiring patterns 42g described above are disposed so as to straddle the second end portion e2 of the reinforcing plate 131 on the board surface of the flexible board 13A.

Further, in the flexible board 13B in Practical Example 2 shown in FIG. 8, the reinforcing patterns which function as the stress relaxation parts 132B are formed using dedicated patterns 43 different from the wiring patterns 42 to be electrically coupled to the drive devices 41. In other words, the dedicated patterns 43 are disposed so as to straddle the second end portion e2 of the reinforcing plate 131 on the board surface of the flexible board 13B. It should be noted that in this case, the dedicated patterns 43 are disposed on a wiring layer different from, for example, the wiring patterns 42. Alternatively, for example, it may be arranged that the wiring layer is made sparse, and the dedicated pattern 43 is inserted between the signal lines. In such a manner, the dedicated patterns 43 are patterns electrically separated from the wiring patterns 42 (the signal wiring patterns 42s, the power supply wiring patterns 42d, and the ground wiring patterns 42g).

Meanwhile, in each of the flexible boards 13C, 13D in Practical Examples 3, 4 shown in FIG. 10 and FIG. 11, the following configuration is adopted. That is, in these flexible boards 13C, 13D, in the signal wiring patterns 42s to be electrically coupled to the drive devices 41, wide portions W having a relatively large wiring width are provided, and the reinforcing patterns which function as the stress relaxation parts 132C, 132D are formed using the wide portions W in the signal wiring patterns 42s. In other words, such wide portions W in the signal wiring patterns 42s are disposed so as to straddle the second end portion e2 of the reinforcing plate 131 on the board surface of the flexible boards 13C, 13D. It should be noted that in the examples in FIG. 10 and FIG. 11, the signal wiring patterns 42s are disposed on the second wiring layer at the reverse surface S2 side in the flexible boards 13C, 13D, and the signal wiring lines are electrically coupled individually to the respective terminals T in the terminal section 130. Further, for example, it may be arranged that the power supply wiring patterns 42d and the ground wiring patterns 42g are disposed on the second wiring layer, and further, these patterns become patterns relatively wider compared to the signal wiring patterns 42s (to dispose the wide portions W) to thereby form the reinforcing patterns.

### Comparative Example 2

It should be noted that in contrast, in the flexible board 203 in Comparative Example 2 shown in FIG. 9, the wide portions W which function as the reinforcing patterns described above are not provided to the signal wiring patterns 42s. Therefore, as described later in detail, the risk that a crack caused by the bend of the flexible board 203 occurs in the vicinity of the second end portion e2 of the reinforcing plate 131 is made high similarly to the case of Comparative Example 1 described above.

### Practical Example 5

Further, in a flexible board 13E in Practical Example 5 shown in FIG. 12, the shape of the second end portion e2 in the reinforcing plate 131 is formed of a nonlinear shape which functions as a stress relaxation part 132E unlike the flexible boards 13A to 13D described above. Further, in the example in FIG. 12, such a nonlinear shape is formed of a corrugated shape. It should be noted that other shapes such as a triangular shape or a concavo-convex shape may be adopted as such a nonlinear shape.

It should be noted that the power supply wiring patterns 42d, the ground wiring patterns 42g, the dedicated patterns 43, and the wide portions W each correspond to a specific example of a “reinforcing pattern” in the present disclosure.

### [Operations and Functions/Advantages]

### (A. Basic Operation of Printer 5)

In the printer 5, a recording operation (a printing operation) of images, characters, and so on to the recording target medium (the recording paper P or the like) is performed using such a jet operation of the ink 9 by the inkjet head 1 as described below. Specifically, in the inkjet head 1 according to the present embodiment, the jet operation of the ink 9 using a shear mode is performed in the following manner.

First, the drive devices 41 on each of the flexible boards 13 (13a, 13b, 13c, and 13d) each apply the drive voltages Vd (the drive signals Sd) to the drive electrodes (the common electrodes and the active electrodes) described above in the actuator plate 111 in the jet section 11. Specifically, each of the drive devices 41 applies the drive voltage Vd to the drive electrodes disposed on the pair of drive walls partitioning the ejection channel described above. Thus, the pair of drive walls each deform so as to protrude toward the dummy channel adjacent to the ejection channel.

On this occasion, it results in that the drive wall makes a flexion deformation to have a V shape centering on the intermediate position in the depth direction in the drive wall. Further, due to such a flexion deformation of the drive wall, the ejection channel deforms as if the ejection channel bulges. As described above, due to the flexion deformation caused by a piezoelectric thickness-shear effect in the pair of drive walls, the volume of the ejection channel increases. Further, by the volume of the ejection channel increasing, the ink 9 is induced into the ejection channel as a result.

Subsequently, the ink 9 induced into the ejection channel in such a manner turns to a pressure wave to propagate to the inside of the ejection channel. Then, the drive voltage Vd to be applied to the drive electrodes becomes 0 (zero) V at the timing at which the pressure wave has reached the nozzle hole Hn of the nozzle plate 112 (or timing around that timing). Thus, the drive walls are restored from the state of the flexion deformation described above, and as a result, the volume of the ejection channel having once increased is restored again.

In such a manner, the pressure inside the ejection channel increases in the process that the volume of the ejection channel is restored, and thus, the ink 9 in the ejection channel is pressurized. As a result, the ink 9 shaped like a droplet is ejected (see FIG. 1) toward the outside (toward the recording paper P) through the nozzle hole Hn. The jet operation (the ejection operation) of the ink 9 in the inkjet head 1 is performed in such a manner, and as a result, the recording operation of images, characters, and so on to the recording paper P is performed.

### (B. Functions/Advantages in Inkjet Head 1)

Then, the functions and the advantages in the inkjet head 1 according to the present embodiment will be described in detail.

### (B-1. Regarding Related-Art Inkjet Head)

First, in the drive board (the flexible board) to be used in the related-art inkjet head, it is common that a connector is mounted on a board at a counterpart side (a coupling destination), and the terminal section of the flexible board is inserted into the connector. Further, when coupling the flexible board to the connector, it is common that a reinforcing plate is provided to an insertion portion (in the vicinity of the terminal section) of the flexible board to the connector, and the thickness of the reinforcing plate is made compatible with a specification of the connector.

Such a flexible board has flexibility and resistance to tension, and bears a certain level of bend, but when a crack occurs, there is a possibility that breakage begins at the crack. Further, in the flexible board, in order to absorb an assembly error and to provide freedom to the board arrangement, the patterns are made sparse to provide flexibility or the patterns are omitted to provide a difference in rigidity to thereby provide a folding point in some cases. In particular, since the end portion (an edge portion) of the reinforcing plate described above is easy to be used as the folding point, in order to further stabilize the folding point, the patterns in the end portion of the reinforcing plate may be made sparse in some cases to support the position at which the flexible board is folded.

However, when the flexible board is used in an ink atmosphere as in the inkjet head, polyimide deteriorates due to an ink component to lose the flexibility of the flexible board in some cases, and the flexible board becomes more fragile against the bend in some cases. In nature, flexible boards have flexibility, and therefore bear a plurality of times of bend, but when excessive stress is repeatedly applied to those deteriorated in material as described above, such a crack as described above may occur in some cases due to fatigue in material.

In particular, the end portion of the reinforcing plate described above has a thickness several times as large as the thickness of the base material made of polyimide, and the material is stretched from the end portion as a starting point when a bend occurs, and therefore, the risk that a crack occurs in polyimide base material thus deteriorated increases. In other words, the end portion of the reinforcing plate may become a starting point of the crack in some cases. It should be noted that when such a crack occurs in the flexible board, copper is exposed on a section of the board as a result. Since there is a risk that copper thus exposed is eroded in such an ink use environment as described above, it can be said that the crack (exposure of copper) of the flexible board is inadmissible.

In this way, in the flexible board (including the flexible boards 103, 203 in Comparative Examples 1, 2 described above) in the related-art inkjet head, there is a possibility that a crack occurs in the vicinity of the end portion (the second end portion e2) of the reinforcing plate to incur the deterioration of the reliability.

### (B-2. Functions/Advantages)

In contrast, in the inkjet head 1 according to the present embodiment, since the flexible boards 13 (13A to 13E) have the following configuration, it is possible to obtain, for example, the following functions and advantages.

That is, first, in the flexible board 13 in the present embodiment, the stress relaxation part 132 is disposed in the vicinity of the second end portion e2 (at the opposite side to the first end portion e1 in which the terminal section 130 is disposed) in the reinforcing plate 131. Thus, since such stress generated when bending the flexible board 13 as described above is relaxed, the possibility that the crack occurs in the flexible board 13 in the vicinity of the second end portion e2 of the reinforcing plate 131 is reduced even under the environment in which the ink 9 is used in the inkjet head 1. As a result, in the present embodiment, compared to Comparative Examples 1, 2 and so on described above, it becomes possible to improve the reliability of the flexible board 13.

Further, when a variety of reinforcing patterns (the power supply wiring patterns 42d, the ground wiring patterns 42g, the dedicated patterns 43, the wide portions W, or the like described above) as the stress relaxation parts 132A to 132D are disposed so as to straddle the second end portion e2 of the reinforcing plate 131 as in, for example, the flexible boards 13A to 13D, the following is achieved. That is, since the rigidity in the vicinity of the second end portion e2 increases, and it becomes difficult for the folding to occur, the possibility that the crack occurs in the flexible board 13 decreases even when, for example, a repetitive bend or an excessive bend occurs. Therefore, as described above, it becomes possible to improve the reliability of the flexible boards 13A to 13D.

In particular, when the reinforcing patterns described above are formed using the wide portions W in the signal wiring patterns 42s as in, for example, the flexible boards 13C, 13D, the following is achieved. That is, the reinforcing patterns can be provided even when the flexible boards 13C, 13D are each, for example, a single-sided-wiring flexible board, which becomes to be realized with a simple configuration.

Further, when the reinforcing patterns described above are formed using the dedicated patterns 43 different from the wiring patterns 42 to be electrically coupled to the drive devices 41 as in, for example, the flexible board 13B, the following is achieved. That is, since the dedicated patterns 43 separated from such wiring patterns 42 are used, it becomes possible to increase the degree of freedom of arrangement of the wiring patterns 42 in the flexible board 13B.

Further, when the second end portion e2 of the reinforcing plate 131 is formed of the nonlinear shape (e.g., the corrugated shape) which functions as the stress relaxation part 132E as in, for example, the flexible board 13E, the following is achieved. That is, bending portions on the flexible board 13E are vertically distributed, and the load in the vicinity of the second end portion e2 is also distributed, and therefore, the fatigue of the material in the flexible board 13E is suppressed, and the possibility that the crack occurs is reduced. Therefore, as described above, it becomes possible to improve the reliability of the flexible board 13E.

### 2. Modified Examples

The present disclosure is described hereinabove citing the embodiment and some practical examples, but the present disclosure is not limited to the embodiment and so on, and a variety of modifications can be adopted.

For example, in the embodiment and so on described above, the description is presented specifically citing the configuration examples (the shapes, the arrangements, the number and so on) of each of the members in the printer and the inkjet head, but those described in the above embodiment and so on are not limitations, and it is possible to adopt other shapes, arrangements, numbers and so on.

Specifically, for example, in the embodiment and so on described above, the description is presented specifically citing the configuration examples (the shapes, the arrangement, the number, and so on) of the flexible boards, the drive devices, a variety of wiring patterns, and so on, but these configuration examples are not limited to those described in the above embodiment and so on. For example, in the embodiment and so on described above, there is described the example when the plurality of drive boards are disposed inside the inkjet head, but this example is not a limitation, and it is possible to arrange that, for example, just one drive board is disposed alone inside the inkjet head. Further, in the embodiment and so on described above, there is described the example when the plurality of drive devices are disposed on the drive board, but this example is not a limitation, and it is possible to arrange that, for example, just one drive device is disposed on the drive board. Further, in the embodiment and so on described above, the shape of the drive device is assumed to be the rectangular shape, but this example is not a limitation, and the shape of the drive device can be, for example, a square shape.

Further, a variety of types of structures can be adopted as the structure of the inkjet head. Specifically, it is possible to adopt, for example, a so-called side-shoot type inkjet head which ejects the ink 9 from a central portion in the extending direction of each of the ejection channels in the actuator plate 111. Alternatively, it is possible to adopt, for example, a so-called edge-shoot type inkjet head for ejecting the ink 9 along the extending direction of each of the ejection channels. Further, the type of the printer is not limited to the type described in the above embodiment and so on, and it is possible to apply a variety of types such as a micro electro-mechanical systems (MEMS) type.

Further, for example, it is possible to apply the present disclosure to either of an inkjet head of a circulation type which uses the ink 9 while circulating the ink 9 between the ink tank and the inkjet head, and an inkjet head of a non-circulation type which uses the ink 9 without circulating the ink 9.

Further, the series of processing described in the above embodiments and so on can be arranged to be performed by hardware (a circuit), or can also be arranged to be performed by software (a program). When it is arranged that the series of processing is performed by the software, the software is constituted by a program group for making the computer perform the functions. The programs can be incorporated in advance in the computer described above to be used by the computer, for example, or can also be installed in the computer described above from a network or a recording medium to be used by the computer.

Further, in the embodiment and so on described above, the description is presented citing the printer 5 (the inkjet printer) as a specific example of the “liquid jet recording apparatus” in the present disclosure, but this example is not a limitation, and it is also possible to apply the present disclosure to other apparatuses than the inkjet printer. In other words, it is also possible to arrange that the “liquid jet head” (the inkjet head) of the present disclosure is applied to other apparatuses than the inkjet printer. Specifically, it is also possible to arrange that the “liquid jet head” of the present disclosure is applied to an apparatus such as a facsimile or an on-demand printer.

In addition, it is also possible to apply the variety of examples described hereinabove in arbitrary combination.

It should be noted that the advantages described in the present specification are illustrative only, but are not a limitation, and other advantages can also be provided.

Further, the present disclosure can also take the following configurations.

A flexible board configured to output a drive signal to be applied to a liquid jet head having a plurality of nozzles, including a drive device or a plurality of drive devices which are disposed on a board surface, and which is configured to generate the drive signal configured to jet a liquid from the nozzles, a terminal section as a portion which is disposed in an end-portion region of the board surface, and which is inserted into a connector on another board, a reinforcing plate which is disposed including the terminal section at a first end portion side on the board surface, and which is configured to adjust a thickness of the board surface, and a stress relaxation part which is disposed in a vicinity of a second end portion at an opposite side to the first end portion in the reinforcing plate, and which is configured to relax stress generated when the flexible board bends.

The flexible board described in (1) above, wherein a reinforcing pattern as the stress relaxation part is disposed so as to straddle the second end portion of the reinforcing plate on the board surface.

The flexible board described in (2) above, wherein the reinforcing pattern is formed using a power supply wiring pattern or a ground wiring pattern to be electrically coupled to the drive device.

The flexible board described in (2) above, wherein a wide portion relatively wider in wiring width is provided in a signal wiring pattern to be electrically coupled to the drive device, and the reinforcing pattern is formed using the wide portion in the signal wiring pattern.

The flexible board described in (2) above, wherein the reinforcing pattern is formed using a dedicated pattern different from a wiring pattern to be electrically coupled to the drive device.

The flexible board described in (1) above, wherein the second end portion of the reinforcing plate is formed of a nonlinear shape which functions as the stress relaxation part.

The flexible board described in (6) above, wherein the nonlinear shape is a corrugated shape.

A liquid jet head including the flexible board described in any of (1) to (7) above, and a jet section which includes the plurality of nozzles configured to jet the liquid based on the drive signal output from the flexible board.

A liquid jet recording apparatus including the liquid jet head described in (8) above.

What is claimed is:

1. A flexible board configured to output a drive signal to be applied to a liquid jet head having a plurality of nozzles, the flexible board comprising:
a drive device or a plurality of drive devices which are disposed on a board surface, and which is configured to generate the drive signal configured to jet a liquid from the nozzles;
a terminal section as a portion which is disposed in an end-portion region of the board surface, and which is inserted into a connector on another board;
a reinforcing plate which is disposed including the terminal section at a first end portion side on the board surface, and which is configured to adjust a thickness of the board surface; and
a stress relaxation part which is disposed in a vicinity of a second end portion at an opposite side to the first end portion in the reinforcing plate, and which is configured to relax stress generated when the flexible board bends.

2. The flexible board according to claim 1, wherein
a reinforcing pattern as the stress relaxation part is disposed so as to straddle the second end portion of the reinforcing plate on the board surface.

3. The flexible board according to claim 2, wherein
the reinforcing pattern is formed using a power supply wiring pattern or a ground wiring pattern to be electrically coupled to the drive device.

4. The flexible board according to claim 2, wherein
a wide portion relatively wider in wiring width is provided in a signal wiring pattern to be electrically coupled to the drive device, and
the reinforcing pattern is formed using the wide portion in the signal wiring pattern.

5. The flexible board according to claim 2, wherein
V the reinforcing pattern is formed using a dedicated pattern different from a wiring pattern to be electrically coupled to the drive device.

6. The flexible board according to claim 1, wherein
the second end portion of the reinforcing plate is formed of a nonlinear shape which functions as the stress relaxation part.

7. The flexible board according to claim 6, wherein
the nonlinear shape is a corrugated shape.

8. A liquid jet head comprising:
the flexible board according to claim 1; and
a jet section which includes the plurality of nozzles configured to jet the liquid based on the drive signal output from the flexible board.

9. A liquid jet recording apparatus comprising the liquid jet head according to claim 8.
